(19) United States
(12) Patent Application Publication
(10) Pub. No.: US 2014/0204305 A1
(43) Pub. Date: Jul. 24, 2014

(54) TFT STRUCTURE, LCD DEVICE, AND METHOD FOR MANUFACTURING TFT

(71) Applicant: SHENZHEN CHINA STAR OPTOELECTRONICS TECHNOLOGY CO., LTD., Shenzhen, Guangdong (CN)

(72) Inventor: Chihyuan Tseng, Shenzhen (CN)

(73) Assignee: SHENZHEN CHINA STAR OPTOELECTRONICS TECHNOLOGY CO., LTD., Shenzhen, Guangdong (CN)

(21) Appl. No.: 13/824,346

(22) PCT Filed: Feb. 27, 2013
(86) PCT No.: PCT/CN2013/071918

§ 371 Date: Mar. 15, 2013

(30) Foreign Application Priority Data
Jan. 23, 2013 (CN) 201310025057.2

(51) Int. Cl. H01L 29/786; G02F 1/1362; H01L 21/3213; G02F 1/1368; H01L 29/66; H01L 29/40

(52) U.S. Cl. CPC H01L 29/7869; H01L 29/66742; H01L 29/40; H01L 21/32133; G02F 1/1368; G02F 1/136286
USPC 349/46; 257/43; 438/151

(57) ABSTRACT

A thin film transistor (TFT) structure includes a first metal layer. The first metal layer is configured with an insulating layer, a surface of the insulating layer corresponding to an area above the first metal layer is configured with an active layer made of an indium gallium zinc oxide (IGZO), a second metal layer is formed on a surface of the active layer, the second metal layer is configured with a gap on an upper surface of the active layer, and a groove is formed at the upper surface of the active layer corresponding to an area of the gap.

### TECHNICAL FIELD

The present disclosure relates to the field of liquid crystal displays (LCDs), and more particularly to a thin film transistor (TFT) structure, an LCD device, and a method for manufacturing the TFT.

### BACKGROUND

Most typical liquid crystal display (LCD) panels use thin film transistors (TFTs) to control deflection of liquid crystal (LC) molecules. As shown in FIG. 1, a traditional manufacturing process for the TFT includes: sequentially forming a gate electrode (GD), a source electrode (SD), and a drain electrode (DD) of the TFT on a glass substrate, and connecting the SD and the DD by an active layer which is usually made of a amorphous silicon (p-Si, N+/a-Si as shown in the FIG. 1). With development in technology, researchers are beginning to use indium gallium zinc oxide (IGZO) as material of the active layer to replace the N+/a-Si (as shown in FIG. 2). Compared with the amorphous silicon, the IGZO has advantages of reduced TFT sizes, integration of a simple external circuit into the panel to enable a mobile device to be light and thin, and two-thirds power reduction compared to before. The IGZO further has advantages of increased a pixel aperture rate of the LCD panel, easily improving image quality, improved electron mobility rate to 20-30 times, and greatly reducing response time of the LCD.

However, in actual use, characteristic and efficiency of the TFT using the IGZO are not ideal. As shown in FIG. 3, middle current slowly increases with voltage, and a current value of more than 10⁻⁶ A is obtained only when the voltage exceeds 10 V. Generally, the voltage of 10 V is defined as Iₒₙ (current when connecting the TFT), and the voltage of −5 V is defined as I_{off} (current when disconnecting the TFT), when Iₒₙ/I_{off} is more than 10⁻⁶ A, the IGZO may be applied to the TFT device. However, in FIG. 3, because Iₒₙ/I_{off} less than 10⁻³ A, the characteristic and efficiency of the typical IGZO TFT are not high.

### SUMMARY

In view of the above-described problems, the aim of the present disclosure is to provide a thin film transistor (TFT) structure, a liquid crystal display (LCD) device, and a method for manufacturing the TFT capable of improving the characteristic and efficiency of the TFT made of an indium gallium zinc oxide (IGZO).

The aim of the present disclosure is achieved by the following technical scheme.

A TFT structure comprises a first metal layer. The first metal layer is configured with an insulating layer, a surface of the insulating layer corresponding to an area above the first metal layer is configured with an active layer made of an IGZO, a second metal layer is formed on a surface of the active layer, the second metal layer is configured with a gap on an upper surface of the active layer, and a groove is formed at the upper surface of the active layer corresponding to an area of the gap.

Furthermore, the gap is used as a boundary by the second metal layer, the second metal layer of a first end of the gap is a source electrode metal layer of the TFT, and the second metal layer of a second end of the gap is a drain electrode metal layer of the TFT. The active layer comprises a first area in contact with the source electrode metal layer, a second area in contact with the drain electrode metal layer, and a third area which connects the first area with the second area. A thickness of the first area is consistent with a thickness of the second area, and a thickness of the third area is less than the thickness of the first area and the second area. The first area of the active layer is flush with the first end of the gap, and the second area of the active layer is flush with the second end of the gap. An upper surface of the third area and second side surfaces of the first area and the second area which are flush with the gap form the groove. This is a specific structure of the active layer. Because the first area of the active layer is flush with the first end of the gap, and because the second area of the active layer is flush with the second end of the gap, a shape of the groove may be consistent with a shape of the gap, and the groove may be directly etched from the gap by using the source electrode metal layer and the drain electrode metal layer as protection layers in the manufacturing process without additionally manufacturing masks, thereby reducing manufacturing cost.

Furthermore, the source electrode metal layer comprises a first, connecting structure which covers the surface of the insulating layer, a second connecting structure in contact with the first connecting structure and a first side surface of the first area of the active layer, and a third connecting structure which covers an upper surface of the first area of the active layer and is connected with the second connecting structure. The drain electrode metal layer comprises a fourth connecting structure which covers the surface of the insulating layer, a fifth connecting structure in contact with the fourth connecting structure and a first side surface of the second area of the active layer, and a sixth connecting structure which covers an upper surface of the second area of the active layer and is connected with the fifth connecting structure. This is a specific structure of the source electrode metal layer and the drain electrode metal layer.

Furthermore, a depth of the groove is 0.1%-95% of the thickness of the first area. The depth of the groove is a distance between the upper surface of the active layer and bottom of the groove. This is a value range of the depth of the groove. When the range exceeds 0.1%, most impure surface materials of the active layer are removed, and adequate active layer is reserved, achieving excellent TFT characteristic.

Furthermore, the depth of the groove is 0.2%-55% of the thickness of the first area. This is a preferable value range of the depth of the groove. Within the range, the impure surface materials of the active layer are basically removed, and adequate active layer is reserved, achieving excel lent TFT characteristic.

Furthermore, an alignment layer covers a surface of the second metal layer and in the gap and the groove, and the alignment layer is used to initially align a direction of liquid crystal (LC) molecules.

Furthermore, a transparent electrode covers a surface of the alignment layer corresponding to the drain electrode metal layer. The transparent electrode is electrically connected with the second metal layer at the second end of the gap to control a deflection angle of the LC molecules.

Furthermore, the gap is used as a boundary by the second metal layer, the second metal layer of a first end of the gap is a source electrode metal layer of the TFT, and the second metal layer of a second end of the gap is a drain electrode metal layer of the TFT. The active layer comprises a first area in contact with the source electrode metal layer, a second area in contact with the drain electrode metal layer. and a third area which connects the first area with the second area. A thickness of the first area is consistent with a thickness of the second area, and a thickness of the third area is less than the thickness of the first area and the second area. The first area of the active layer is flush with the first end of the gap. and the second area of the active layer is flush with the second end of the gap. An upper surface of the third area and second side surfaces of the first area and the second area which are flush with the gap form the groove. A depth of the groove is 0.1%-95% of the thickness of the first area. An alignment layer covers a surface of the second metal layer and in the gap and the groove. A transparent electrode that is electrically connected with the drain electrode metal layer covers a surface of the alignment layer corresponding to the drain electrode metal layer. The source electrode metal layer comprises a first connecting structure which covers the surface of the insulating layer, a second connecting structure in contact with the first connecting structure and a first side surface of the first area of the active layer, and a third connecting structure which covers an upper surface of the first area of the active layer and is connected with the second connecting structure. The drain electrode metal layer comprises a fourth connecting structure which covers the surface of the insulating layer, a fifth connecting structure in contact with the fourth connecting structure and a first side surface of the second area of the active layer, and a sixth connecting structure which covers an upper surface of the second area of the active layer and is connected with the fifth connecting structure.

An LCD device comprises the TFT structure of the present disclosure.

A method for manufacturing a TFT comprises:

A: sequentially forming a first metal layer; an insulating layer, an active layer made of an indium gallium zinc oxide (IGZO), and a source electrode metal layer and a drain electrode which cover a surface of the active layer, and forming a gap on an upper surface of the active layer between the source electrode metal layer and the drain electrode metal layer; and

B: etching a groove in the surface of the active layer using the source electrode metal layer and the drain electrode metal layer as protection layers.

The inventor finds by research that a manufacturing process of a typical TFT made of the IGZO comprises; forming the second metal layer on the active layer made of the IGZO by sputtering and the like, etching the gap on the active layer by chemical etching and dividing the second metal layer into two parts, and forming the source electrode metal layer and the drain electrode metal layer of the TFT. When the second metal layer is being formed on the active layer, the second metal layer is combined with a surface material of the IGZO of the active layer, which causes the material of the active layer to be impure, and characteristic and efficiency of the TFT to be poor. In the present disclosure, because further etching is performed at the gap of the second metal, the groove is etched in the surface of the active layer, the impure surface material of the active layer is removed, purity of the material of the active layer is increased, and thus the characteristic and efficiency of the TFT are increased.

### BRIEF DESCRIPTION OF FIGURES

FIG. 1 is a structural diagram of a thin film transistor (TFT) made of a amorphous silicon of the prior art;

FIG. 2 is a structural diagram of a TFT made of an indium gallium zinc oxide (IGZO) of the prior art;

FIG. 3 is a curve diagram of a characteristic of a TFT made of an IGZO of the prior art;

FIG. 4 is a structural diagram of a TFT of an example of the present disclosure;

FIG. 5 is a curve diagram of a characteristic of a TFT of an example of the present disclosure; and

FIG. 6 is a schematic diagram of a method of an example of the present disclosure.

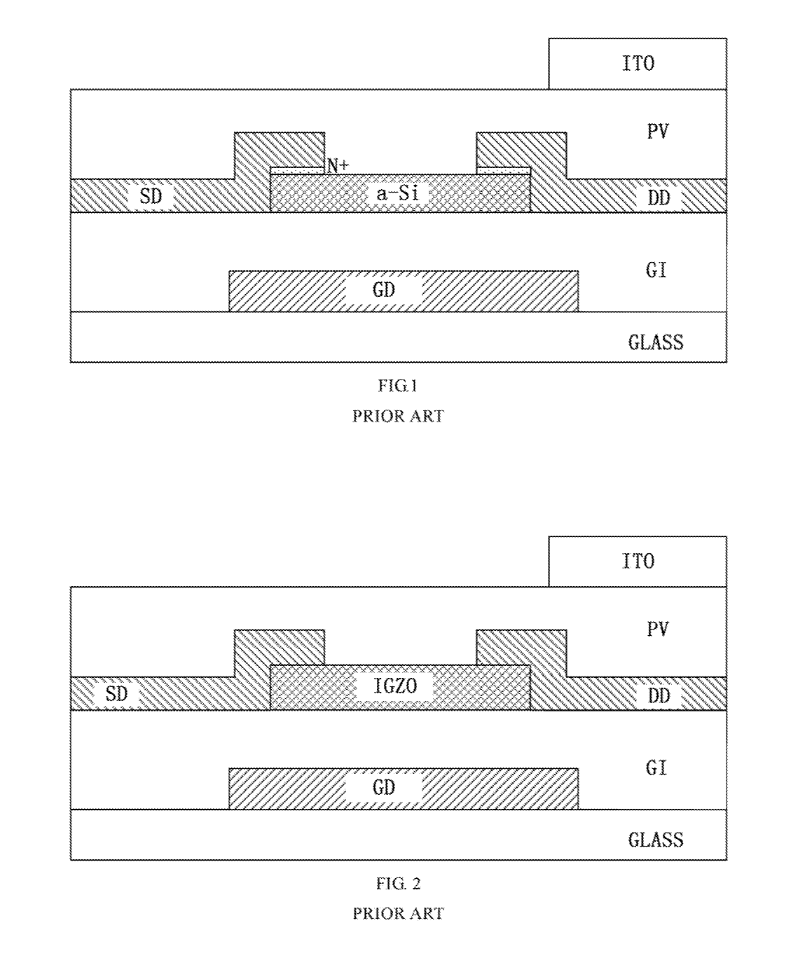

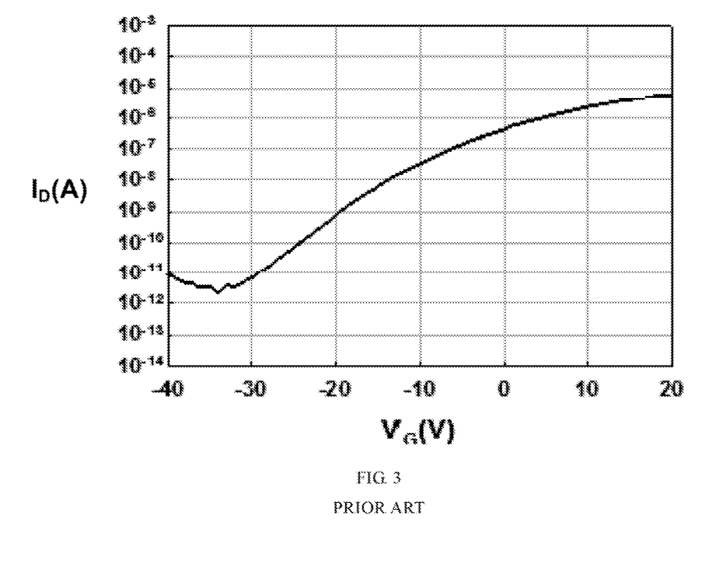

### DETAILED DESCRIPTION

A liquid crystal display (LCD) device comprises a thin film transistor (TFT) structure. The TFT structure comprises a first metal layer, the first metal layer is configured with an insulating layer, a surface of the insulating layer corresponding to an area above the first metal layer is configured with a active layer made of an indium gallium zinc oxide (IGZO), a second metal layer is formed on a surface of the active layer, the second metal layer is configured with a gap on an upper surface of the active layer, and a groove is formed at the upper surface of the active layer corresponding to an area of the gap.

The inventor finds by research that a manufacturing process of a typical TFT made of the IGZO comprises; forming the second metal layer on the active layer made of the IGZO by sputtering and the like, etching the gap on the active layer by chemical etching and dividing the second metal layer into two parts, and forming a source electrode metal layer and a drain electrode metal layer of the TFT. When the second metal layer is being formed on the active layer, the second metal layer is combined with a surface material of the IGZO of the active layer, which causes material of the active layer to be impure, and characteristic and efficiency of the TFT to be poor. In the present disclosure, because further etching is performed at the gap of the second metal, the groove is etched in the surface of the active layer, the impure surface material of the active layer is removed, purity of the material of the active layer is increased, and thus the characteristic and efficiency of the TFT are increased.

The present disclosure is further described in detail in accordance with the figures and the exemplary examples.

As shown in FIG. 4, an TFT structure comprises a first metal layer (GD) 10 (namely a gate electrode metal layer of the TFT), the first metal layer (GD) 10 is configured with an insulating layer (GI) 20, a surface of the insulating layer (GI) 20 corresponding to an area above the first metal layer (GD) 10 is configured with an active layer made of an IGZO (IGZO) 60, a second metal layer 30 is formed on a surface of the active layer (IGZO) 60, the second metal layer 30 is configured with a gap 64 on an upper surface of the active layer (IGZO) 60, and the upper surface of the active layer (IGZO) 60 corresponding to an area of the gap 64 is configured with a groove 70. The gap 64 is used as a boundary by the second metal layer 30, the second metal layer 30 of a first end of the gap 64 is a source electrode metal layer (SD) 40 of the TFT, and the second metal layer 30 of a second end of the gap 64 is a drain electrode metal layer (DD) 50 of the TFT. The active layer (IGZO) 60 comprises a first area 61 in contact with the source electrode metal layer (SD) 40, a second area 62 in contact with the drain electrode metal layer (DD) 50, and a third area 63 which connects the first area 61 with the second area 62. A thickness of the first area 61 is consistent with a thickness of the second area 62, and a thickness of the third area 63 is less than the thickness of the first area 61 and the second area 62. The first area 61 is flush with the first end of the gap 64, and the second area 62 is flush with the second end of the gap 64. An upper surface of the third area 63 and second side surfaces of the first area 61 and the second area 62 which are flush with the gap 64 form the groove 70. A depth of the groove 70 is 0.1%-95% of the thickness of the first area 61, preferably 0.2%-55%.

An alignment layer (PV) 80 covers a surface of the second metal layer and in the gap 64 and the groove 70. A transparent electrode (ITO) 90 that is electrically connected with the drain electrode metal layer (DD) 50 covers a surface of the alignment layer (PV) 80 corresponding to the drain electrode metal layer (DD) 50. The source electrode metal layer (SD) 40 comprises a first connecting structure 41 which covers the surface of the insulating layer (GI) 20. a second connecting structure 42 in contact with the first connecting structure 41 and a first side surface of the first area 61 of the active layer (IGZO) 60, and a third connecting structure 43 which covers an upper surface of the first area 63 of the active layer (IGZO) 60 and is connected with the second connecting structure 42. The drain electrode metal layer (DD) 50 comprises a fourth connecting structure 51 which covers the surface of the insulating layer (GI) 20, a fifth connecting structure 52 in contact with the fourth connecting structure 51 and a first side surface of the second area 62 of the active layer (IGZO) 60, and a sixth connecting structure 53 which covers an upper surface of the second area 62 of the active layer (IGZO) 60 and is connected with the fifth connecting structure 52. The alignment layer (PV) 80 may initially align a direction of LC molecules. The transparent electrode (ITO) 90 is electrically connected with the drain electrode metal layer (DD) 50 to control a deflection angle of the LC molecules.

In the example, because the first area 61 of the active layer (IGZO) 60 is flush with the first end of the gap 64, and because the second area 62 of the active layer (IGZO) 60 is flush with the second end of the gap 64, a shape of the groove 70 may be consistent with a shape of the gap 64, and the groove 70 may be directly etched from the gap 64 by using the source electrode metal layer (SD) 40 and the drain electrode metal layer (DD) 50 as protection layers in the manufacturing process without additionally manufacturing masks, thereby reducing manufacturing cost. A substrate of the present disclosure may be made of glass or other transparent material, and typical mature technology such as chemical etching, physical etching, and the like may be used for etching.

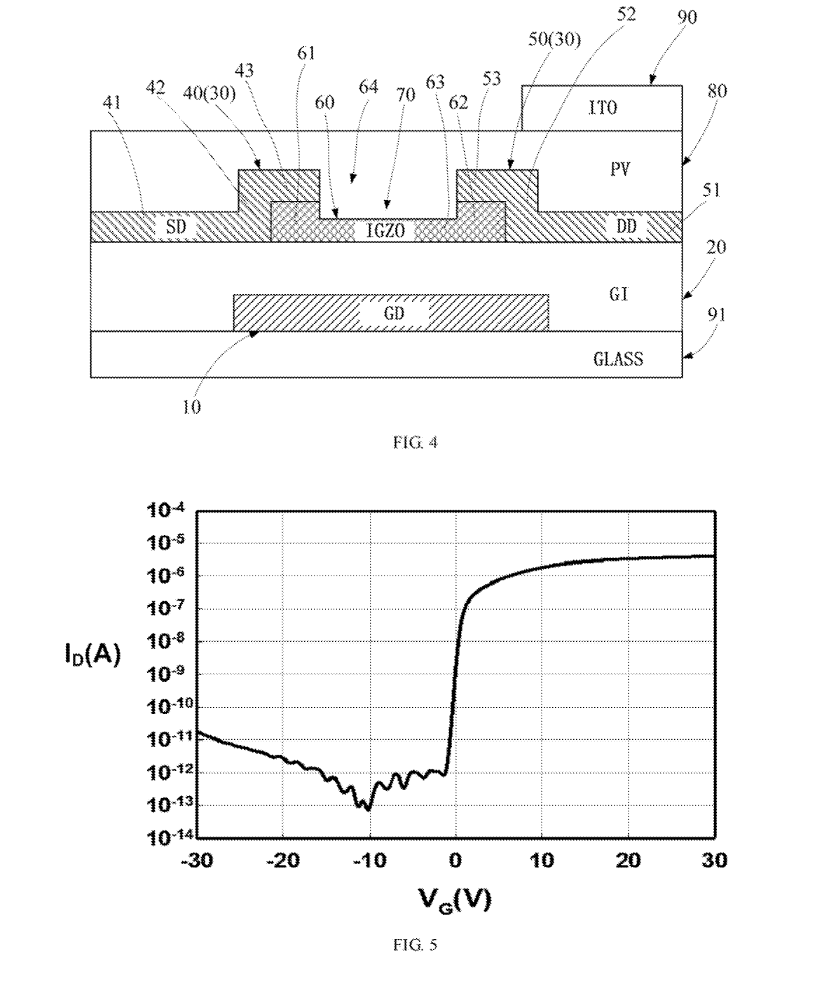

FIG. 5 is a curve diagram of a characteristic of the TFT of the present disclosure using the IGZO material in which the impure surface material of the active layer is removed. When the gate electrode voltage of the TFT is increased from 0 V to 10 V, current quickly rises with the voltage, slope is steep, and the TFT obtains high current within a short voltage range to drive the LCD, Thus, after the technical scheme of the present disclosure is performed, the characteristic and efficiency of the TFT may be significantly increased.

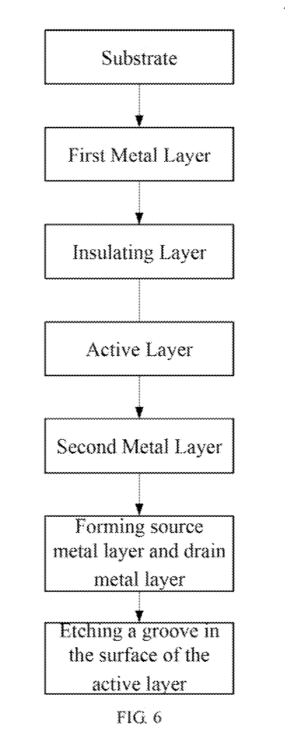

As shown in FIG. 6, the present disclosure further provides a method for manufacturing a TFT, comprising steps;

A: sequentially forming a first metal layer, an insulating layer, an active layer made of an IGZO. and a source electrode metal layer and a drain electrode which cover a surface of the active layer, and forming a gap on an upper surface of the active layer between the source electrode metal layer and the drain electrode metal layer; and

B: etching a groove in the surface of the active layer using the source electrode metal layer and the drain electrode metal layer as protection layers.

The present disclosure is described in detail in accordance with the above contents with the specific preferred examples. However, this present disclosure is not limited to the specific examples. For the ordinary technical personnel of the technical field of the present disclosure, on the premise of keeping the conception of the present disclosure, the technical personnel can also make simple deductions or replacements, and all of which should be considered to belong to the protection scope of the present disclosure.

We claim:

1. A thin film transistor (TFT) structure, comprising;
a first metal layer,
wherein the first metal layer is configured with an insulating layer, a surface of the insulating layer corresponding to an area above the first metal layer is configured with an active layer made of an indium gallium zinc oxide (IGZO), a second metal layer is formed on a surface of the active layer, the second metal layer is configured with a gap on an upper surface of the active layer, and a groove is formed at the upper surface of the active layer corresponding to an area of the gap.

2. The thin film transistor (TFT) structure of claim 1, wherein an alignment layer covers a surface of the second metal layer and in the gap and the groove.

3. The thin film transistor (TFT) structure of claim 2, wherein a transparent electrode covers a surface of the alignment layer corresponding to the drain electrode metal layer.

4. The thin film transistor (TFT) structure of claim 1, wherein the gap is used as a boundary by the second metal layer, the second metal layer of a first end of the gap is a source electrode metal layer of the TFT, and the second metal layer of a second end of the gap is a drain electrode metal layer of the TFT;
the active layer comprises a first area in contact with the source electrode metal layer, a second area in contact with the drain electrode metal layer, and a third area which corresponds to the gap; a shape of the third area is consistent with a shape of the gap; a thickness of the first area is consistent with a thickness of the second area, and a thickness of the third area is less than the thickness of the first area and the second area.

5. The thin film transistor (TFT) structure of claim 4, wherein the source electrode metal layer comprises a first connecting structure which covers the surface of the insulating layer, a second connecting structure in contact with the first connecting structure and a first side surface of the first area of the active layer, and a third connecting structure which covers an upper surface of the first area of the active layer and is connected with the second connecting structure;
the drain electrode metal layer comprises a fourth connecting structure which covers the surface of the insulating layer, a fifth connecting structure in contact with the fourth connecting structure and a first side surface of the second area of the active layer, and a sixth connecting structure which covers an upper surface of the second area of the active layer and is connected with the fifth connecting structure.

6. The thin film transistor (TFT) structure of claim 5, wherein an alignment layer covers a surface of the second metal layer and in the gap and the groove.

7. The thin film transistor (TFT) structure of claim 6, wherein a transparent electrode covers a surface of me alignment layer corresponding to the drain electrode metal layer.

8. The thin film transistor (TFT) structure of claim 4, wherein a depth of the groove is 0.1%-95% of a maximum thickness of the active layer.

9. The thin film transistor (TFT) structure of claim 8, wherein the depth of the groove is 0.2%-55% of the thickness of the first area of the active layer.

10. The thin film transistor (TFT) structure of claim 1, wherein the gap is used as a boundary by the second metal layer, the second metal layer of a first end of the gap is a source electrode metal layer of the TFT, and the second metal layer of a second end of the gap is a drain electrode metal layer of the TFT;
the active layer comprises a first area in contact with the source electrode metal layer, a second area in contact with the drain electrode metal layer, and a third area which connects the first area with the second area; a thickness of the first area is consistent with a thickness of the second area, and a thickness of the third area is less than the thickness of the first area and the second area; the first area of the active layer is flash with the first end of the gap, and the second area of the active layer is flush with the second end of the gap; an upper surface of the third area, and second side surfaces of the first area and the second area which are flush with the gap form the groove; a depth of the groove is 0.1%-95% of the thickness of the first area;
an alignment layer covers a surface of the second metal layer and in the gap and the groove, a transparent electrode that is electrically connected with the drain electrode metal layer covers a surface of the alignment layer corresponding to the drain electrode metal layer;
the source electrode metal layer comprises a first connecting structure which covers the surface of the Insulating layer, a second connecting structure In contact with the first connecting structure and a first side surface of the first area of the active layer, and a third connecting structure which covers an upper surface of the first area of the active layer and is connected with the second connecting structure; the drain electrode metal layer comprises a fourth connecting structure which covers the surface of the insulating layer, a fifth connecting structure in contact with the fourth connecting structure and a first side surface of the second area of the active layer, and a sixth connecting structure which covers an upper surface of the second area of the active layer and is connected with the fifth connecting structure.

11. A liquid crystal display (LCD) device, comprising:
a thin film transistor (TFT) structure,
wherein the TFT structure comprises a first metal layer; the first metal layer is configured with an insulating layer, a surface of the insulating layer corresponding to an area above the first metal layer is configured with an active layer made of an indium gallium zinc oxide (IGZO), a second metal layer is formed on a surface of the active layer, the second metal layer is configured with a gap on an upper surface of the active layer, and a groove is formed at the upper surface of the active layer corresponding to an area of the gap.

12. The liquid crystal display (LCD) device of claim 11, wherein the gap is used as a boundary by the second metal layer, the second metal layer of the first end of the gap is a source electrode metal layer of the thin film transistor (TFT), and the second metal layer of the second end of the gap is a drain electrode metal layer of the TFT;
the active layer comprises a first area in contact with the source electrode metal layer, a second area in contact with the drain electrode metal layer, and a third area which corresponds to the gap; a shape of the third area is consistent with a shape of the gap; a thickness of the first area is consistent with a thickness of the second area, and a thickness of the third area is less than the thickness of the first area and the second area.

13. The liquid crystal display (LCD) device of claim 12, wherein the source electrode metal layer comprises a first connecting structure which covers the surface of the insulating layer, a second connecting structure in contact with the first connecting structure and a first side surface of the first area of the active layer, and a third connecting structure which covers an upper surface of the first area of the active layer and is connected with the second connecting structure;
the drain electrode metal layer comprises a fourth connecting structure which covers the surface of the insulating layer, a fifth connecting structure in contact with the fourth connecting structure and a first, side surface of the second area of the active layer, and a sixth connecting structure which covers an upper surface of the second area of the active layer and is connected with the fifth connecting structure.

14. The liquid crystal display (LCD) device of claim 12, wherein a depth of the groove is 0.1%-95% of a maximum thickness of the active layer.

15. The liquid crystal display (LCD) device of claim 14, wherein the depth of the groove is 0.2%-55% of the thickness of the first area of the active layer.

16. The liquid crystal display (LCD) device of claim 11, wherein an alignment layer covers a surface of the second metal layer and in the gap and the groove.

17. The liquid crystal display (LCD) device of claim 16, wherein a transparent electrode covers a surface of the alignment layer corresponding to the drain electrode metal layer.

18. The liquid crystal display (LCD) device of claim 11, wherein the gap is used as a boundary by the second metal layer, the second metal layer of a first end of the gap is a source electrode metal layer of the thin film transistor (TFT), and the second metal layer of a second end of the gap is a drain electrode metal layer of the TFT;
the active layer comprises a first area in contact with the source electrode metal layer, a second area in contact with the drain electrode metal layer, and a third area which connects the first area with the second area; a thickness of the first area is consistent with a thickness of the second area, and a thickness of the third area is less than the thickness of the first area and the second area; the first area of the active layer is flush with the first end of the gap, and the second area of the active layer is flush with the second end of the gap; an upper surface of the third area, and second side surfaces of the first area and the second area which are flush with the gap form the groove; a depth of the groove is 0.1%-95% of the thickness of the first area;
an alignment layer covers a surface of the second metal layer and in the gap and the groove; a transparent electrode that is electrically connected with the drain electrode metal layer covers a surface of the alignment layer corresponding to the drain electrode metal layer;
the source electrode metal layer comprises a first connecting structure which covers the surface of the insulating layer, a second connecting structure in contact with the first connecting structure and a first side surface of the first area of the active layer, and a third connecting structure which covers an upper surface of the first area of the active layer and is connected with the second connecting structure; the drain electrode metal layer comprises a fourth connecting structure which covers the surface of the insulating layer, a fifth connecting structure in contact with the fourth connecting structure and a first side surface of the second area of the active layer, and a sixth connecting structure which covers an upper surface of the second area of the active layer and is connected with the fifth connecting structure.

19. A method for manufacturing a thin film transistor (TFT), comprising:
A: sequentially forming a first metal layer, an insulating layer, an active layer made of an indium gallium zinc oxide (IGZO), and a source electrode metal layer and a drain electrode cover a surface of the active layer, and forming a gap on an upper surface of the active layer between the source electrode metal layer and the drain electrode metal layer;
B: etching a groove in the surface of the active layer using the source electrode metal layer and the drain electrode metal layer as protection layers.
